(19) United States
(12) Patent Application Publication
(10) Pub. No.: US 2015/0179794 A1
(43) Pub. Date: Jun. 25, 2015

(54) SEMICONDUCTOR DEVICE AND METHOD OF MANUFACTURING THE SAME

(71) Applicant: Hyundai Motor Company, Seoul (KR)

(72) Inventors: Kyoung-Kook HONG, Hwaseong-si (KR); Dae Hwan Chun, Gwangmyeong-si (KR); Jong Seok Lee, Suwon-si (KR); Youngkyun Jung, Seoul (KR); Su Bin Kang, Busan (KR)

(73) Assignee: Hyundai Motor Company, Seoul (KR)

(21) Appl. No.: 14/314,813

(22) Filed: Jun. 25, 2014

(30) Foreign Application Priority Data
Dec. 24, 2013 (KR) 10-2013-0162931

(51) Int. Cl. H01L 29/78; H01L 21/02; H01L 29/66; H01L 29/16; H01L 29/22

(52) U.S. Cl. CPC H01L 29/7827; H01L 29/1608; H01L 29/22; H01L 29/66666; H01L 21/02565

(57) ABSTRACT

Disclosed are a semiconductor device and a method of manufacturing a semiconductor device. The device may include an n− type epitaxial layer disposed on a first surface of an n+ type silicon carbide substrate, a p type epitaxial layer disposed on the n− type epitaxial layer, an n+ region disposed on the p type epitaxial layer, a trench passing through the p type epitaxial layer and the n+ region and disposed on the n− type epitaxial layer, a p+ region disposed on the n− type epitaxial layer and separated from the trench, a gate insulating layer positioned in the trench, a gate electrode positioned on the gate insulating layer, an oxide layer positioned on the gate electrode, a source electrode positioned on the n+ region, the oxide layer, and the p+ region, and a drain electrode positioned on a second surface of the n+ type silicon carbide substrate, in which channels are positioned on both sides of the trench.

### CROSS-REFERENCE TO RELATED APPLICATION

The present application claims priority of Korean Patent Application Number 10-2013-0162931 filed on Dec. 24, 2013, the entire contents of which application are incorporated herein for all purposes by this reference.

### BACKGROUND OF INVENTION

1. Field of Invention

The present invention relates to a semiconductor device including silicon carbide (SiC) and a method of manufacturing the same.

2. Description of Related Art

Recently, according to enlargement and high capacity of applications, there is a need for a power semiconductor device to provide a high breakdown voltage, a high current, and a high-speed switching characteristic.

In such a power semiconductor device, a low on resistance or a low saturated voltage is required in order to lower power loss in a conduction state while a very large current flows. Further, a characteristic endurable to a backward high voltage of a PN junction which is applied to both ends of the power semiconductor device in an off state or at the moment when the switch is turned off, that is, a high breakdown voltage characteristic is basically required.

A metal oxide semiconductor field effect transistor (MOSFET) among the power semiconductor devices is most commonly used as a general field effect transistor in a digital circuit and an analog circuit.

In the MOSFET using silicon carbide (SiC), an interface state between a silicon oxide layer serving as a gate insulating layer and silicon carbide is not good, which influences a flow of electrons and a current passing through a channel generated at a lower end of the silicon oxide layer, and as a result, mobility of the electrons is very low. Particularly, since an etching process is required when a trench gate is formed, worse electron mobility is shown.

Further, deterioration of the electron mobility may be minimized, but in this case, a thickness of the silicon oxide layer serving as the gate insulating layer is increased due to a low threshold voltage. Since the silicon oxide layer is difficult to grow in silicon carbide, a level of difficulty in the process is increased.

The information disclosed in this Background section is only for enhancement of understanding of the general background of the invention and should not be taken as an acknowledgement or any form of suggestion that this information forms the prior art already known to a person skilled in the art.

### SUMMARY OF INVENTION

The present invention has been made in an effort to provide a semiconductor device and a method of manufacturing the same having advantages of reducing on-resistance in a silicon carbide MOSFET to which a trench gate is applied and reducing difficulty in the process of manufacturing the semiconductor device.

Various aspects of the present invention provide a semiconductor device, including: an n− type epitaxial layer disposed on a first surface of an n+ type silicon carbide substrate; a p type epitaxial layer disposed on the n− type epitaxial layer; an n+ region disposed on the p type epitaxial layer; a trench passing through the p type epitaxial layer and the n+ region, and disposed on the n− type epitaxial layer; a p+ region disposed on the n− type epitaxial layer and separated from the trench; a gate insulating layer positioned in the trench; a gate electrode positioned on the gate insulating layer; an oxide layer positioned on the gate electrode; a source electrode positioned on the n+ region, the oxide layer, and the p+ region; and a drain electrode positioned on a second surface of the n+ type silicon carbide substrate, in which channels are positioned on both sides of the trench, and the channels include a first channel which is an inversion layer channel and a second channel which is positioned below the first channel and is an accumulation layer channel.

The first channel may be disposed in the n− type epitaxial layer on both sides of the trench, and the second channel may be disposed in the p type epitaxial layer on both sides of the trench. A thickness of the p+ region may be larger than a sum of thicknesses of the p type epitaxial layer and the n+ region. An upper surface of the p+ region may be positioned on an extended line of an upper surface of the n+ region. A lower surface of the p+ region may be positioned below a lower surface of the p type epitaxial layer or below an extended line of the lower surface of the p type epitaxial layer. The p type epitaxial layer and the n+ region may be disposed between the trench and the p+ region.

Various other aspects of the present invention provide a method of manufacturing a semiconductor device, including: forming an n− type epitaxial layer on a first surface of an n+ type silicon carbide substrate; forming a preliminary p type epitaxial layer on the n− type epitaxial layer; forming a p+ region by injecting p+ ions into both edges of the preliminary p type epitaxial layer; forming an n+ region and a p type epitaxial layer between the n+ region and the n− type epitaxial layer by injecting n+ ions into the preliminary p type epitaxial layer; forming a trench at the n+ region, the p type epitaxial layer, and the n− type epitaxial layer; forming a gate insulating layer in the trench; forming a gate electrode on the gate insulating layer; forming an oxide layer on the gate electrode; forming a drain electrode on a second surface of the n+ type silicon carbide substrate; and forming a source electrode on the p+ region, the n+ region, and the oxide layer, in which the trench passes through the n+ region and the p type epitaxial layer, channels are formed on both sides of the trench, and the channels include a first channel which is an inversion layer channel and a second channel which is positioned below the first channel and is an accumulation layer channel.

As such, according to the present invention, since channels include an inversion layer channel and an accumulation layer channel positioned below the inversion layer channel, on-resistance is reduced, and a manufacturing process is facilitated.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a cross-sectional view of an exemplary semiconductor device according to the present invention.

FIGS. 2 to 7 are diagrams sequentially illustrating an exemplary method of manufacturing a semiconductor device according to the present invention.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

In the drawings, the thickness of layers, films, panels, regions, etc., are exaggerated for clarity. It will be understood that when a layer is referred to as being “on” another layer or substrate, it can be directly on the other layer or substrate, or intervening them may also be present.

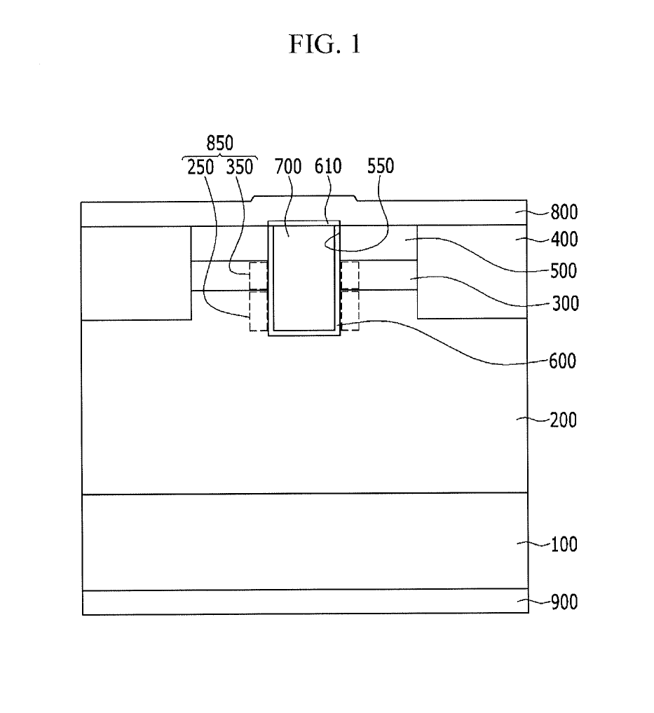

FIG. 1 is a cross-sectional view of a semiconductor device according to various embodiments of the present invention. Referring to FIG. 1, in a semiconductor device according to various embodiments of the present invention, an n− type epitaxial layer 200, a p type epitaxial layer 300, and an n+ region 500 are sequentially disposed on a first surface of an n+ type silicon carbide substrate 100. Further, a p+ region 400 is disposed on an edge of the n− type epitaxial layer 200.

A trench 550 is formed in the n− type epitaxial layer 200, the p type epitaxial layer 300, and the n+ region 500. The trench 550 passes through the p type epitaxial layer 300 and the n+ region 500, and is formed at a part of the n− type epitaxial layer 200.

The p+ region 400 is separated from the trench 550, and disposed on both sides of the trench 550, respectively. As a result, the p type epitaxial layer 300 and the n+ region 500 are disposed between the trench 550 and the p+ region 400.

The p+ region 400 contacts edges of the p type epitaxial layer 300 and the n+ region 500, and an upper surface of the p+ region 400 is positioned on an extended line of an upper surface of the n+ region 500. A thickness of the p+ region 400 is larger than a sum of thicknesses of the p type epitaxial layer 300 and the n+ region 500. As a result, a lower surface of the p+ region 400 is positioned below a lower surface of the p type epitaxial layer 300.

By the structure, a lower edge of the p+ region 400 contacts the n− type epitaxial layer 200, and as a result, there is an electric field dispersion effect in an off state of the semiconductor device. Accordingly, a breakdown voltage of the semiconductor device increases.

A gate insulating layer 600 is formed in the trench 550, and a gate electrode 700 is formed on the gate insulating layer 600. An oxide layer 610 is formed on the gate electrode 700 and the gate insulating layer 600. The gate electrode 700 fills the trench 550, and the gate insulating layer 600 and the oxide layer 610 may be made of silicon dioxide (SiO₂).

A source electrode 800 is formed on the p+ region 400, the n+ region 500, and the oxide layer 610. A drain electrode 900 is formed on a second surface of the n+ type silicon carbide substrate 100.

Here, channels 850 of the semiconductor device are formed in the p type epitaxial layer 300 on both sides of the trench 550 and the n− type epitaxial layer 200 on both sides of the trench 550. The channels 850 include a first channel 250 and a second channel 350.

The first channel 250 is an accumulation layer channel formed in the n− type epitaxial layer 200 on both sides of the trench 550, and the second channel 350 is an inversion layer channel formed in the p type epitaxial layer 300 on both sides of the trench 550. That is, the first channel 250 as the accumulation layer channel is positioned below the second channel 350 as the inversion layer channel.

When a voltage is applied to the gate electrode 700, electrons and a current flow in the channel 850 from the source electrode 800 to the drain electrode 900. In this case, as the first channel 250 as the accumulation layer channel is positioned at a lower end of the channel 850, the electrons and the current are diffused, and thus mobility of the electrons and the current may be improved. As a result, on-resistance of the semiconductor device may be reduced.

As such, the semiconductor device according to various embodiments of the present invention may have an effect of reducing the on-resistance, which is an advantage of the accumulation layer channel, because the channel 850 includes the first channel 250 as the accumulation layer channel.

Further, the semiconductor device according to various embodiments of the present invention has an advantage of the inversion layer channel because the channel 850 includes the second channel 350 as the inversion layer channel.

Further, the thickness of the gate insulating layer 600 of the semiconductor device including only the inversion layer channel is smaller than the thickness of the gate insulating layer 600 of the semiconductor device including only the accumulation layer channel due to a sufficient threshold voltage. As a result, difficulty in the process is relatively decreased. That is, in the semiconductor device according to various embodiments of the present invention, a manufacturing process may be facilitated due to a sufficient threshold voltage which is the advantage of the inversion layer channel.

Next, comparison of characteristics of a semiconductor device according to an Example of the present invention and a semiconductor device according to Comparative Examples will be described with reference to Table 1.

Table 1 illustrates a result of simulating characteristics of a semiconductor device according to the Example of the present invention and a semiconductor device according to the Comparative Examples. In Table 1, Comparative Example 1 is a semiconductor device including only an inversion layer channel, and Comparative Example 2 is a semiconductor device including only an accumulation layer channel.

TABLE 1

| | Comparative | Comparative | |
|---|---|---|---|
| Classification | Example 1 | Example 2 | Example |
| Thickness of gate insulating | 50 | 300 | 70 |
| layer (nm) | | | |
| Breakdown voltage(V) | 858 | 810 | 996 |
| Threshold voltage(V) | 4.887 | 2.624 | .428 |
| On-resistance (mΩ/cm²) | 3.150 | 2.646 | 2.717 |
| Performance index (MV/cm²) | 234 | 248 | 365 |

Referring to Table 1, in the semiconductor device according to Comparative Example 1, it can be seen that since the gate insulating layer may be formed to have a relatively small thickness due to the sufficient threshold voltage, difficulty in the process is reduced. However, it can be seen that since the on-resistance is high, the flow of electrons and current is slow, and thus the current density is low.

In the semiconductor device according to Comparative Example 2, it can be seen that since the on-resistance is low, the flow of electrons and current is fast, and thus the current density is high. However, since the gate insulating layer is formed to have a relatively large thickness due to a relatively low threshold voltage, difficulty in the process is increased.

In the case of the semiconductor device according to the Example, the thickness of the gate insulating layer is little different from the thickness of the gate insulating layer of the semiconductor device according to Comparative Example 1, and the on-resistance is little different from the on-resistance of the semiconductor device according to Comparative Example 2. As a result, it can be seen that the semiconductor device according to the Example has both the advantage of the semiconductor device according to Comparative Example 1 in that difficulty in the process is reduced and the advantage of the semiconductor device according to Comparative Example 2 in that the on-resistance is low.

Further, in the case of a performance index representing performance of the semiconductor device, it can be seen that the performance index of the semiconductor device according to the Example is larger than that of the semiconductor devices according to Comparative Examples 1 and 2. That is, it can be seen that the semiconductor device according to various embodiments of the present invention including the accumulation layer channel and the inversion layer channel has higher performance than the semiconductor device according to Comparative Example 1 including only the accumulation layer channel and the semiconductor device according to Comparative Example 2 including only the inversion layer channel. Here, the performance index is a value obtained by dividing a squared value of the breakdown voltage by an on-resistance value, as an index generally used to determine performance of the semiconductor device.

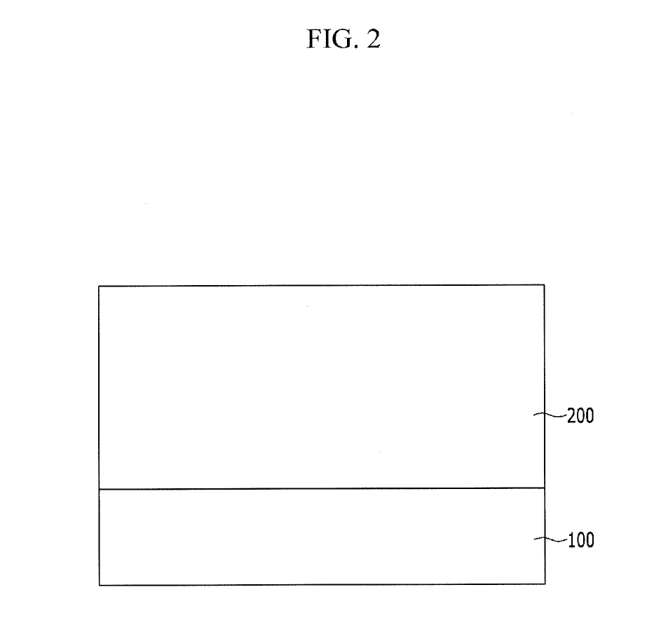

Next, a method of manufacturing a semiconductor device according to various embodiments of the present invention will be described in detail with reference to FIGS. 2 to 7, and FIG. 1. FIGS. 2 to 7 are diagrams sequentially illustrating a method of manufacturing a semiconductor device according to various embodiments of the present invention.

Referring to FIG. 2, the n+ type silicon carbide substrate 100 is prepared, and the n− type epitaxial layer 200 is formed on the first surface of the n+ type silicon carbide substrate 100 through a first epitaxial growth.

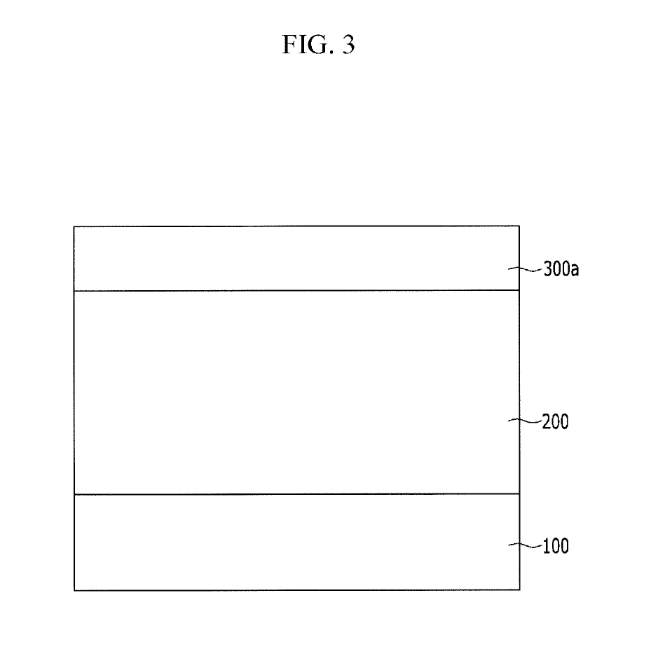

Referring to FIG. 3, a preliminary p type epitaxial layer 300a is formed on the n− type epitaxial layer 200 through a second epitaxial growth. Further, the preliminary p type epitaxial layer 300a is not limited to the epitaxial growth, but may be formed by injecting p ions into the n− type epitaxial layer 200.

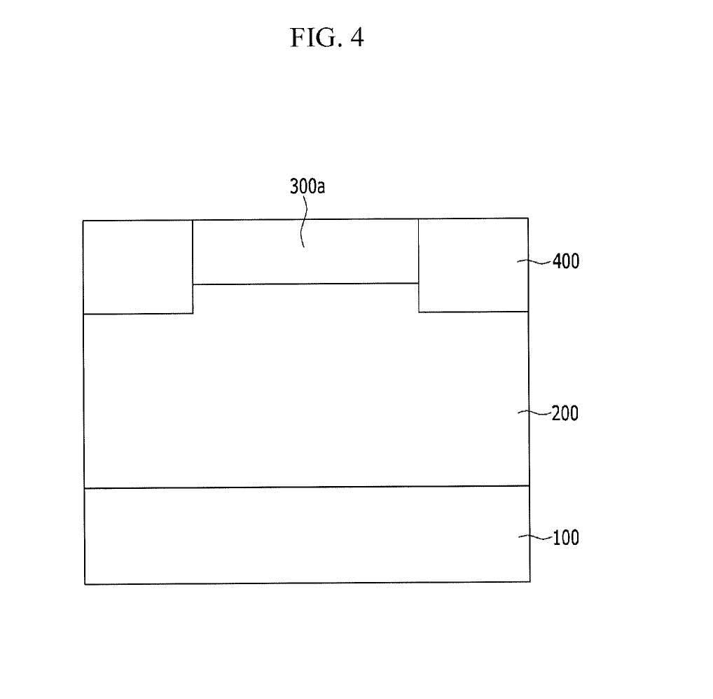

Referring to FIG. 4, the p+ region 400 is formed by injecting p+ ions into both edges of the preliminary p type epitaxial layer 300a. The p+ ions are injected into the preliminary p type epitaxial layer 300a and a part of the n− type epitaxial layer 200 positioned below the preliminary p type epitaxial layer 300a. As a result, a lower surface of the p+ region 400 is positioned below an upper surface of the preliminary p type epitaxial layer 300a.

Here, the injection of the p+ ions uses a mask. That is, only both edges of the preliminary p type epitaxial layer 300a are exposed by using the mask, and the p+ ions are injected into the exposed both edges of the preliminary p type epitaxial layer 300a. As such, since the p+ region 400 is formed by injecting the p+ ions, the trench for the p+ region 400 need not be formed.

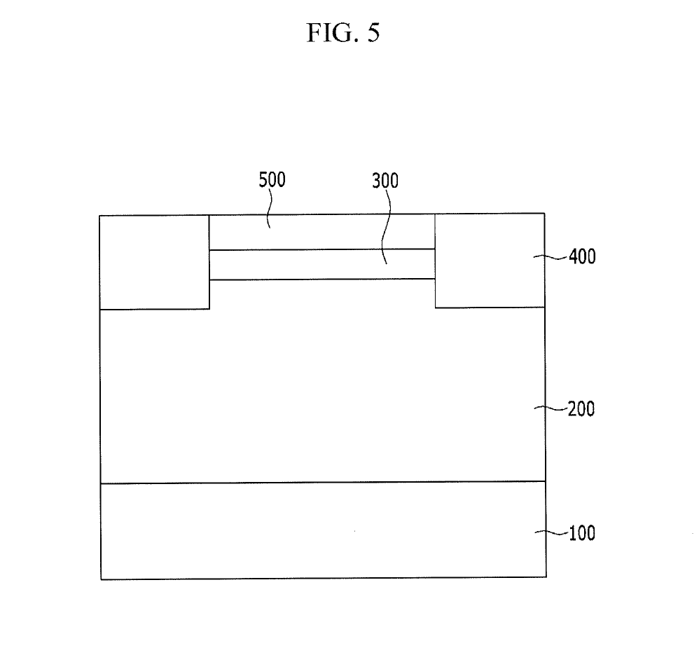

Referring to FIG. 5, the n+ region 500 is formed by injecting n+ ions into the preliminary p type epitaxial layer 300a. The n+ ions are not injected up to a boundary of the preliminary p type epitaxial layer 300a and the p type epitaxial layer 300. As a result, the n+ region 500 is separated from the n− type epitaxial layer 200, and the p type epitaxial layer 300 is formed between the n+ region 500 and the n− type epitaxial layer 200. The edge of the n+ region 500 contacts the p+ region 400. The upper surface of the n+ region 500 is positioned on an extended line of the upper surface of the p+ region 400. A thickness of the p+ region 400 is larger than a sum of thicknesses of the n+ region 500 and the p type epitaxial layer 300. Here, the injection of the n+ ions uses a mask. That is, the p+ region 400 is covered and the preliminary p type epitaxial layer 300a is exposed by using the mask, and thus the n+ ions are injected into the exposed preliminary p type epitaxial layer 300a.

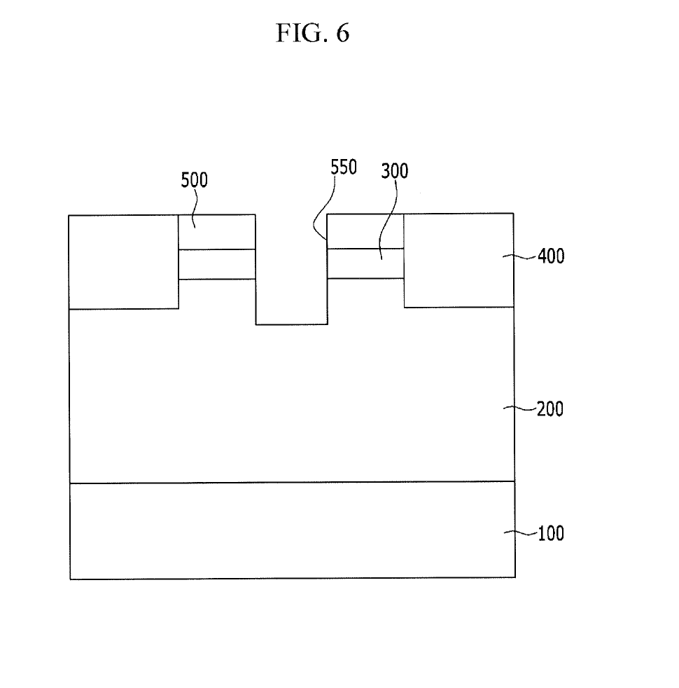

Referring to FIG. 6, the trench 550 is formed by etching the n− type epitaxial layer 200, the p type epitaxial layer 300, and the n+ region 500. The trench 550 passes through the p type epitaxial layer 300 and the n+ region 500, and is formed at a part of the n− type epitaxial layer 200.

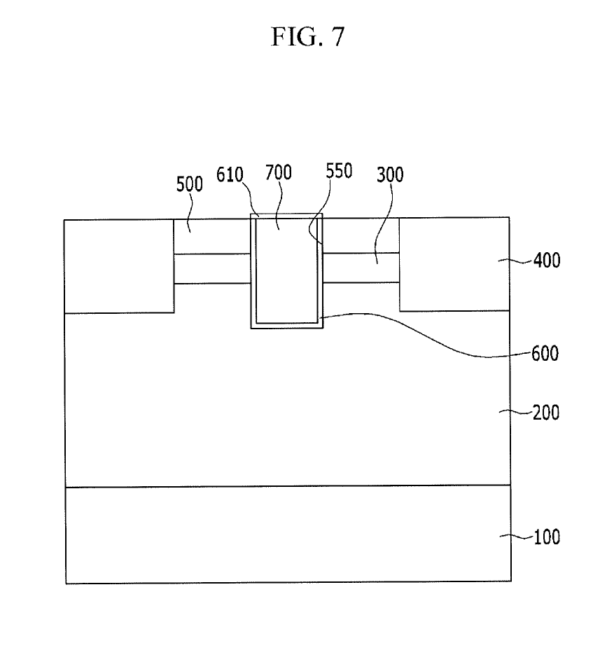

Referring to FIG. 7, the gate insulating layer 600 is formed inside the trench 550 by using silicon dioxide (SiO₂) or other suitable materials, the gate electrode 700 is formed on the gate insulating layer 600, and then the oxide layer 610 is formed on the gate electrode 700 and the gate insulating layer 600 by using silicon dioxide (SiO₂) or other suitable materials. The gate electrode 700 is formed to fill the trench 550.

Referring to FIG. 1, the source electrode 800 is formed on the p+ region 400, the oxide layer 610, and the n+ region 500, and the drain electrode 900 is formed on the second surface of the n+ type silicon carbide substrate 100.

For convenience in explanation and accurate definition in the appended claims, the terms “upper” or “lower”, and etc. are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof It is intended that the scope of the invention be defined by the Claims appended hereto and their equivalents.

1. A semiconductor device, comprising:
an n− type epitaxial layer disposed on a first surface of an n+ type silicon carbide substrate;
a p type epitaxial layer disposed on the n− type epitaxial layer;
an n+ region disposed on the p type epitaxial layer;
a trench passing through the p type epitaxial layer and the n+ region, and disposed on the n− type epitaxial layer;
a p+ region disposed on the n− type epitaxial layer and separated from the trench;
a gate insulating layer positioned in the trench;
a gate electrode positioned on the gate insulating layer;
an oxide layer positioned on the gate electrode;
a source electrode positioned on the n+ region, the oxide layer, and the p+ region; and
a drain electrode positioned on a second surface of the n+ type silicon carbide substrate,
wherein channels are positioned on both sides of the trench, and
the channels include a first channel which is an inversion layer channel and a second channel which is positioned below the first channel and is an accumulation layer channel.

2. The semiconductor device of claim 1, wherein the first channel is disposed in the n− type epitaxial layer on both sides of the trench, and
the second channel is disposed in the p type epitaxial layer on both sides of the trench.

3. The semiconductor device of claim 2, wherein a thickness of the p+ region is larger than a sum of thicknesses of the p type epitaxial layer and the n+ region.

4. The semiconductor device of claim 3, wherein an upper surface of the p+ region is positioned on an extended line of an upper surface of the n+ region.

5. The semiconductor device of claim 4, wherein a lower surface of the p+ region is positioned below a lower surface of the p type epitaxial layer or below an extended line of the lower surface of the p type epitaxial layer.

6. The semiconductor device of claim 5, wherein the p type epitaxial layer and the n+ region are disposed between the trench and the p+ region.

7. A method of manufacturing a semiconductor device, comprising:
forming an n− type epitaxial layer on a first surface of an n+ type silicon carbide substrate;
forming a preliminary p type epitaxial layer on the n− type epitaxial layer;
forming a p+ region by injecting p+ ions into both edges of the preliminary p type epitaxial layer;
forming an n+ region and a p type epitaxial layer between the n+ region and the n− type epitaxial layer by injecting n+ ions into the preliminary p type epitaxial layer;
forming a trench at the n+ region, the p type epitaxial layer, and the n− type epitaxial layer;
forming a gate insulating layer in the trench;
forming a gate electrode on the gate insulating layer;
forming an oxide layer on the gate electrode;
forming a drain electrode on a second surface of the n+ type silicon carbide substrate; and
forming a source electrode on the p+ region, the n+ region, and the oxide layer,
wherein the trench passes through the n+ region and the p type epitaxial layer,
channels are formed on both sides of the trench, and
the channels include a first channel which is an inversion layer channel and a second channel which is positioned below the first channel and is an accumulation layer channel.

8. The method of claim 7, wherein the first channel is formed in the n− type epitaxial layer on both sides of the trench, and the second channel is formed in the p type epitaxial layer on both sides of the trench.

9. The method of claim 8, wherein a thickness of the p+ region is larger than a sum of thicknesses of the p type epitaxial layer and the n+ region.

10. The method of claim 9, wherein a lower surface of the p+ region is positioned below a lower surface of the preliminary p type epitaxial layer.

11. The method of claim 10, wherein an upper surface of the n+ region is positioned on an extended line of an upper surface of the p+ region.

12. The method of claim 7, wherein the p type epitaxial layer and the n+ region are disposed between the trench and the p+ region.
